(19) United States
(12) Patent Application Publication
(10) Pub. No.: US 2025/0207825 A1
(43) Pub. Date: Jun. 26, 2025

(54) CRYOGENIC DEVICE

(71) Applicant: SUMITOMO HEAVY INDUSTRIES, LTD., Tokyo (JP)

(72) Inventor: Atsushi HASHIMOTO, Yokosuka-shi (JP)

(21) Appl. No.: 19/076,897

(22) Filed: Mar. 11, 2025

Related U.S. Application Data
(63) Continuation of application No. PCT/JP2023/030594, filed on Aug. 24, 2023.

(30) Foreign Application Priority Data
Oct. 27, 2022 (JP) 2022-172327

(51) Int. Cl. F25B 9/14; F25B 9/10; H01F 6/04

(52) U.S. Cl. CPC F25B 9/14; F25B 9/10; H01F 6/04

(57) ABSTRACT

A cryogenic device includes: a vacuum chamber; a superconducting coil that is disposed in the vacuum chamber; a cryocooler that is installed in the vacuum chamber to cool the superconducting coil; a current introduction terminal that is installed in the vacuum chamber and is connected to the superconducting coil; and a condensation water reservoir that is provided around an exposed portion, which is exposed from the vacuum chamber, of at least one of the cryocooler or the current introduction terminal, below the exposed portion.

### CROSS-REFERENCE TO RELATED APPLICATIONS

This is a bypass continuation of International PCT Application No. PCT/JP2023/030594, filed on Aug. 24, 2023, which claims priority to Japanese Patent Application No. 2022-172327, filed on Oct. 27, 2022, which are incorporated by reference herein in their entirety.

### BACKGROUND

### Technical Field

Certain embodiments of the present invention relate to a cryogenic device.

### Description of Related Art

In the related art, a cryogenic device including a cryocooler and a vacuum chamber is known. For example, various objects to be cooled, such as superconducting units such as a superconducting coil, other units used in a cryogenic environment, and a cryogenic refrigerant for cooling such units, are accommodated in the vacuum chamber. The cryocooler is used to cool the objects to be cooled.

### SUMMARY

According to an embodiment of the present invention, there is provided a cryogenic device including: a vacuum chamber; a superconducting coil that is disposed in the vacuum chamber; a cryocooler that is installed in the vacuum chamber to cool the superconducting coil; a current introduction terminal that is installed in the vacuum chamber and is connected to the superconducting coil; and a condensation water reservoir that is provided around an exposed portion, which is exposed from the vacuum chamber, of at least one of the cryocooler or the current introduction terminal, below the exposed portion.

### BRIEF DESCRIPTION OF THE DRAWINGS

FIG. 1 is a diagram schematically showing a cryogenic device according to an embodiment.

FIG. 2 is a diagram schematically showing a condensation water reservoir according to a modification example.

FIG. 3 is a diagram schematically showing a cryogenic device according to another embodiment.

### DETAILED DESCRIPTION

In a case where the maintenance of the cryogenic device is performed, the energization of the superconducting coil may be stopped or a cooling operation to be performed by the cryocooler may be stopped. In this case, a thermal balance in the cryogenic device changes from that during the normal operation of the cryogenic device and the superconducting coil having been cryogenically cooled in the vacuum chamber serves as a cooling source, so that a component of the cryogenic device connected to the superconducting coil in a heat transferable manner can be cooled. In this way, for example, portions exposed to an ambient environment on an outer surface of the vacuum chamber, such as a current introduction terminal for supplying a current to the superconducting coil and a drive unit of the cryocooler, are cooled, and condensation or freezing of moisture in the ambient air may occur on the exposed portions. For this reason, there is a concern that condensation water spreads to the surroundings on the cryogenic device and cause adverse effects. For example, an iron material, such as a magnetic shield or a yoke surrounding the vacuum chamber, may be wet, which may cause rust. Alternatively, the adhesion of water droplets to an energization unit such as the current introduction terminal may lead to a risk of a trouble in an electrical system such as an electric leakage.

It is desirable to deal with condensation that may occur in a cryogenic device.

Embodiments of the present invention will be described in detail below with reference to the drawings. The same or equivalent components, members, and processing in the description and the drawings will be denoted by the same reference numerals and the repeated description thereof will be appropriately omitted. The scale and shape of each part to be shown in the drawing are conveniently set to facilitate the description, and are not interpreted in a limited way unless otherwise specified. The embodiments are exemplary and do not limit the scope of the present invention in any way. All features to be described in the embodiments and combinations thereof are not necessarily essential to the present invention.

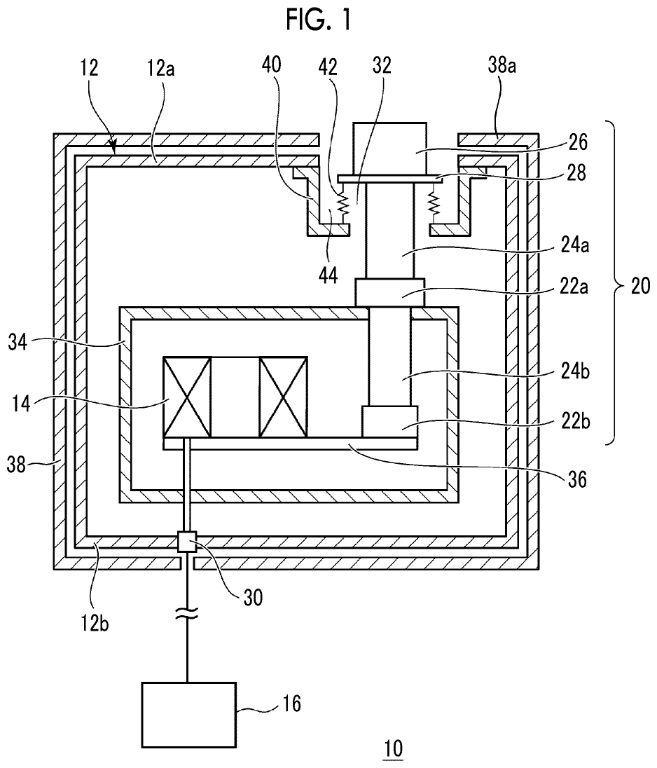

FIG. 1 is a diagram schematically showing a cryogenic device 10 according to an embodiment. An internal structure of the cryogenic device 10 is schematically shown in FIG. 1. The cryogenic device 10 is a superconducting magnet device, and includes a vacuum chamber 12, a superconducting coil 14 that is disposed in the vacuum chamber 12, a cryocooler 20 that is installed in the vacuum chamber 12 to cool the superconducting coil 14, and a current introduction terminal 30 that is installed in the vacuum chamber 12 and is connected to the superconducting coil 14. The superconducting magnet device may be used as, for example, a magnetic field source for a single crystal pulling device.

The vacuum chamber 12 is a thermally insulated vacuum chamber that provides a cryogenic vacuum environment suitable for bringing the superconducting coil 14 into a superconducting state, and is also called a cryostat. Usually, the vacuum chamber 12 has a columnar shape or a cylindrical shape having a hollow portion at a center portion. Accordingly, the vacuum chamber 12 includes a top plate 12a and a bottom plate 12b that have a substantially flat circular or annular shape, and a cylindrical side wall (a cylindrical outer peripheral wall, or a cylindrical outer peripheral wall and a cylindrical inner peripheral wall that are coaxially disposed) that connects the top plate 12a and the bottom plate 12b. The vacuum chamber 12 is made of, for example, a metal material, such as stainless steel, or another suitable high-strength material to withstand ambient pressure (for example, atmospheric pressure).

The superconducting coil 14 is connected to an external power source 16 through the current introduction terminal 30. The current introduction terminal 30 corresponds to a tip of a current path to the superconducting coil 14 provided in the vacuum chamber 12, and the current path is also often called a current lead. The current introduction terminal 30 is a hermetic terminal that is provided on a wall surface of the vacuum chamber 12 and introduces a current from the outside of the vacuum chamber 12 to the inside of the vacuum chamber 12 while maintaining airtightness inside the vacuum chamber 12. Although only one current introduction terminal 30 is shown in FIG. 1 for simplicity, at least a pair of current introduction terminals 30 (and at least a pair of current leads) is generally provided on a positive electrode side and a negative electrode side. The current introduction terminal 30 is provided in the bottom plate 12b of the vacuum chamber 12 in this example. An excitation current is supplied from the external power source 18 to the superconducting coil 14 through the current introduction terminal 30 in a state where the superconducting coil 14 is cooled to a cryogenic temperature equal to or lower than a superconducting transition temperature by the cryocooler 20. Accordingly, the superconducting coil 14 can generate a strong magnetic field.

The cryocooler 20 includes a compressor (not shown) for refrigerant gas (for example, helium gas) and an expander that is also called a cold head, and a refrigeration cycle of the cryocooler 20 is formed by the compressor and the expander, so that cryogenic cooling is provided. The cryocooler 20 is, for example, a two-stage Gifford-McMahon (GM) cryocooler. The cryocooler 20 includes a first cooling stage 22a and a second cooling stage 22b as a low-temperature section that is to be cooled to a cryogenic temperature. These cooling stages are disposed in the vacuum chamber 12. The first cooling stage 22a and the second cooling stage 22b are made of, for example, a metal material such as copper or other materials having high thermal conductivity.

Further, the cryocooler 20 includes a first cylinder 24a, a second cylinder 24b, a cold head drive unit 26, and a mounting flange 28. The first cylinder 24a connects the mounting flange 28 to the first cooling stage 22a, and the second cylinder 24b connects the first cooling stage 22a to the second cooling stage 22b. The cold head drive unit 26 is provided on a side opposite to the first cylinder 24a and is attached to the mounting flange 28.

For example, the first cylinder 24a and the second cylinder 24b are members having a cylindrical shape, and a diameter of the second cylinder 24b is smaller than a diameter of the first cylinder 24a. The first cylinder 24a and the second cylinder 24b are coaxially disposed, and a lower end of the first cylinder 24a is rigidly connected to an upper end of the second cylinder 24b. In a case where the cryocooler 20 is a GM cryocooler, a first displacer and a second displacer, in which a regenerator material is built, are accommodated in the first cylinder 24a and the second cylinder 24b, respectively. The first displacer and the second displacer are connected to each other and can reciprocate along the first cylinder 24a and the second cylinder 24b, respectively. The first cylinder 24a and the second cylinder 24b are usually made of, for example, a metal material having a lower thermal conductivity than the first cooling stage 22a and the second cooling stage 22b, such as stainless steel.

The cold head drive unit 26 includes a motor and a connection mechanism that connects the motor to the first displacer and the second displacer to convert a rotating motion output from the motor into reciprocating motions of the first displacer and the second displacer. Further, the cold head drive unit 26 includes a pressure switching valve that periodically switches internal pressures of the first cylinder 24a and the second cylinder 24b to a high pressure and a low pressure, and the pressure switching valve is also driven by the same motor.

In this example, a cold head of the cryocooler 20 is installed on the top plate 12a of the vacuum chamber 12. The top plate 12a of the vacuum chamber 12 is provided with an opening portion 32 through which the cold head is inserted into the vacuum chamber 12. The cold head is vertically installed in the vacuum chamber 12 such that the cold head drive unit 26 faces upward and the first cooling stage 22a and the second cooling stage 22b face downward. The cold head drive unit 26 is exposed to an ambient environment (for example, an environment under a room temperature and an atmospheric pressure) from the vacuum chamber 12.

During the operation of the cryocooler 20, the first cooling stage 22a is cooled to a first cooling temperature, for example, a temperature in a range of 30 K to 80 K, and the second cooling stage 22b is cooled to a second cooling temperature lower than the first cooling temperature, for example, a temperature in a range of 3 K to 20 K.

A radiant heat shield 34 is disposed in the vacuum chamber 12 together with the low-temperature section of the cryocooler 20 and the superconducting coil 14. The radiant heat shield 34 is thermally coupled to the first cooling stage 22a and is cooled to the first cooling temperature. The radiant heat shield 34 is directly attached to the first cooling stage 22a and is thermally coupled to the first cooling stage 22a. Alternatively, the radiant heat shield 34 may be attached to the first cooling stage 22a via a heat transfer member having flexibility or stiffness. The radiant heat shield 34 is made of, for example, a metal material such as copper or other materials having high thermal conductivity. The radiant heat shield 34 is disposed to surround the superconducting coil 14, the second cooling stage 22b of the cryocooler 20, and other low-temperature sections that are to be cooled to the second cooling temperature, and can thermally protect these low-temperature sections from radiant heat from the outside.

The superconducting coil 14 is thermally coupled to the second cooling stage 22b via a heat transfer member 36 and is cooled to the second cooling temperature. The heat transfer member 36 may be a heat transfer member having flexibility or stiffness, and is made of, for example, a metal material such as copper or other materials having high thermal conductivity. Alternatively, the superconducting coil 14 may be directly attached to the second cooling stage 22b.

The vacuum chamber 12 may include a magnetic shield 38 on the outside thereof to suppress the leakage of a magnetic field, which is generated by the superconducting coil 14, to the outside. The magnetic shield 38 covers the top plate 12a and the bottom plate 12b of the vacuum chamber 12 and a side wall connecting the top plate 12a and the bottom plate 12b. The magnetic shield 38 is made of a magnetic material such as iron. An opening portion that receives the cold head drive unit 26 of the cryocooler 20 is formed in an upper plate 38a of the magnetic shield 38 adjacent to the top plate 12a of the vacuum chamber 12, and the cold head drive unit 26 is disposed to protrude upward from the magnetic shield 38 as shown in FIG. 1.

In this embodiment, the vacuum chamber 12 includes a first tubular portion 40 that extends downward into the vacuum chamber 12 from the opening portion 32 of the top plate 12a and a second tubular portion 42 that extends downward into the first tubular portion 40 from an exposed portion (that is, the cold head drive unit 26) which is exposed from the vacuum chamber 12 of the cryocooler 20. A double-tube, which is formed of the first tubular portion 40 and the second tubular portion 42, connects the top plate 12a of the vacuum chamber 12 to the cold head drive unit 26 at the opening portion 32 while maintaining airtightness inside the vacuum chamber 12.

The first tubular portion 40 has, for example, the shape of a hollow tube such as a cylinder, and is made of, for example, a metal material such as stainless steel or other appropriate materials. The first tubular portion 40 may include an inner flange, to which the second tubular portion 42 is to be attached, at a lower end thereof.

The second tubular portion 42 connects the cold head drive unit 26 (more specifically, the mounting flange 28) to the first tubular portion 40. The second tubular portion 42 may be deformable, and may be, for example, a bellows. Alternatively, the second tubular portion 42 may be made of, for example, a metal material such as stainless steel like the first tubular portion 40, and may rigidly connect the cold head drive unit 26 and the first tubular portion 40.

The first tubular portion 40 may be deformable instead of (or together with) the second tubular portion 42, and may be, for example, a bellows. In a case where at least one of the first tubular portion 40 or the second tubular portion 42 is made deformable, the thermal shrinkage of the low-temperature section that may occur during cryogenic cooling can be absorbed.

As described above, in a case where the maintenance of the cryogenic device 10 is performed, a thermal balance in the cryogenic device 10 may change from that during the normal operation of the cryogenic device 10 due to the stop of the energization of the superconducting coil 14 or the stop of the cooling performed by the cryocooler 20. Accordingly, the superconducting coil 14 having been cryogenically cooled in the vacuum chamber 12 serves as a cooling source, so that a component of the cryogenic device 10 connected to the superconducting coil 14 in a heat transferable manner, for example, the cold head drive unit 26 of the cryocooler 20 can be cooled. For this reason, moisture in the ambient air may condense on the cold head drive unit 26 during the maintenance work of the cryogenic device 10. In a case where condensation water spreads to the surroundings, the condensation water may adhere to the magnetic shield 38. Since the magnetic shield 38 is made of an iron material, the adhering water may cause rust.

As shown in FIG. 1, an annular (for example, circular annular) recess is formed between the first tubular portion 40 and the second tubular portion 42 below the top plate 12a of the vacuum chamber 12. Since this recess is provided around the cold head drive unit 26 below the cold head drive unit 26, the recess can function as a condensation water reservoir 44 that receives the condensation water. That is, water droplets condensed on the cold head drive unit 26 flow down to the condensation water reservoir 44 and are collected in the condensation water reservoir 44. The condensation water stored in the condensation water reservoir 44 may be removed as necessary (for example, during maintenance work or at the end of the maintenance work) by wiping or the like, or may be left to naturally evaporate. In this way, it is possible to reduce or prevent the spread of the condensation water to the surroundings. Since the condensation water reservoir 44 is provided on one side of the top plate 12a of the vacuum chamber 12 opposite to the upper plate 38a of the magnetic shield 38 (that is, on the lower side of the top plate 12a), the occurrence of rust on the magnetic shield 38 caused by contact with the condensation water is also reduced or prevented.

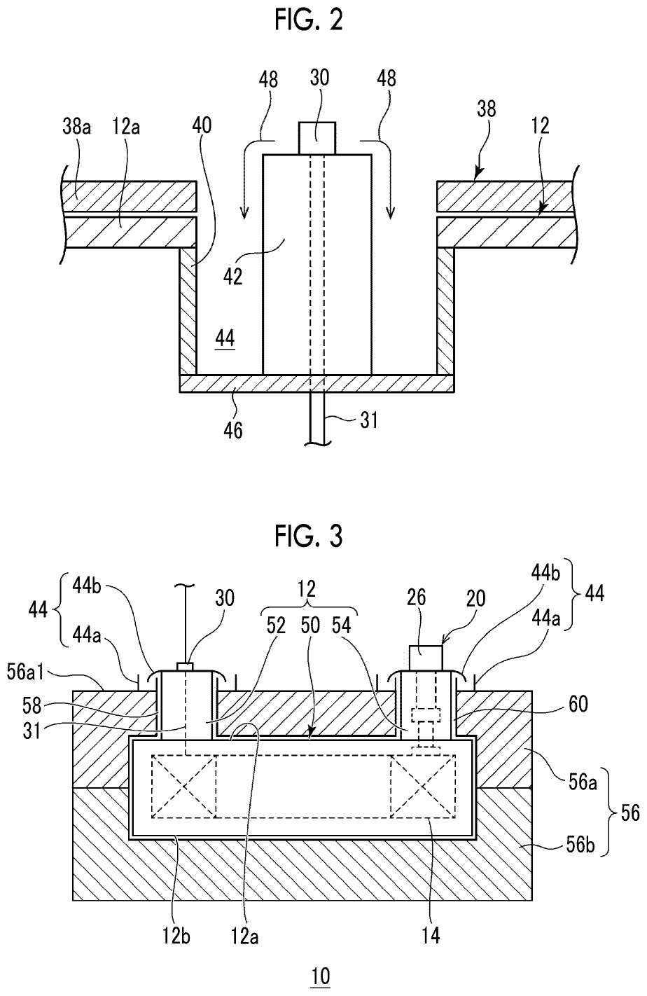

FIG. 2 is a diagram schematically showing a condensation water reservoir 44 according to a modification example. In the cryogenic device 10 described with reference to FIG. 1, the current introduction terminal 30 is provided in the bottom plate 12b of the vacuum chamber 12. However, the cryogenic device 10 can also be designed to adopt the current introduction terminal 30 provided in the top plate 12a of the vacuum chamber 12. Since condensation may also occur on the current introduction terminal 30 as in the cold head drive unit 26 described above, the condensation water reservoir 44 according to the embodiment may be applied to the current introduction terminal 30.

As shown in FIG. 2, a vacuum chamber 12 includes a first tubular portion 40 that extends downward into the vacuum chamber 12 from an opening portion 32 of a top plate 12a and a second tubular portion 42 that extends downward into the first tubular portion 40 from an exposed portion which is exposed from the vacuum chamber 12, in this case, from the current introduction terminal 30. A double-tube, which is formed of the first tubular portion 40 and the second tubular portion 42, connects the top plate 12a of the vacuum chamber 12 to the current introduction terminal 30 at the opening portion 32 while maintaining airtightness inside the vacuum chamber 12. The second tubular portion 42 may be a tubular case that accommodates a current lead 31 connected to the current introduction terminal 30. At least one of the first tubular portion 40 or the second tubular portion 42 may include, for example, a bellows, and may be deformable.

An annular recess that functions as the condensation water reservoir 44 is formed between the first tubular portion 40 and the second tubular portion 42 below the top plate 12a of the vacuum chamber 12. The condensation water reservoir 44 is provided around the current introduction terminal 30 below the current introduction terminal 30. Lower ends of the first tubular portion 40 and the second tubular portion 42 are connected to each other by a bottom plate 46 of the condensation water reservoir 44. The bottom plate 46 may be an inner flange of the first tubular portion 40 as described above, may be an outer flange of the second tubular portion 42, or may be a member separate from the first tubular portion 40 and the second tubular portion 42.

As shown by arrows 48, water droplets adhering to the current introduction terminal 30 due to condensation flow down to the condensation water reservoir 44 and are collected in the condensation water reservoir 44. In this way, it is possible to reduce or prevent the spread of the condensation water to the surroundings. Since the condensation water reservoir 44 is provided on one side of the top plate 12a of the vacuum chamber 12 opposite to the upper plate 38a of the magnetic shield 38, the occurrence of rust on the magnetic shield 38 caused by contact with the condensation water is also reduced or prevented. Further, the risk of a trouble in an electrical system, such as an electric leakage, can also be reduced.

FIG. 3 is a diagram schematically showing a cryogenic device 10 according to another embodiment. The cryogenic device 10 is a superconducting magnet device, and includes a vacuum chamber 12, a superconducting coil 14 that is disposed in the vacuum chamber 12, a cryocooler 20 that is installed in the vacuum chamber 12 to cool the superconducting coil 14, and a current introduction terminal 30 that is installed in the vacuum chamber 12 and is connected to the superconducting coil 14. The superconducting magnet device may be used as, for example, a magnetic field source for a cyclotron.

The vacuum chamber 12 includes a vacuum chamber body 50 that accommodates the superconducting coil 14, a first tubular portion 52 that accommodates a current lead 31, and a second tubular portion 54 that accommodates the cryocooler 20. The vacuum chamber body 50 includes a top plate 12a, a bottom plate 12b, and a side wall connecting the top plate 12a and the bottom plate 12b. The first tubular portion 52 protrudes upward from the top plate 12a of the vacuum chamber body 50, and extends to an exposed portion of the current lead 31 exposed from the vacuum chamber 12, that is, to the current introduction terminal 30.

In other words, the current introduction terminal 30 is exposed to an environment around the vacuum chamber 12 at an upper end of the first tubular portion 52. The second tubular portion 54 protrudes upward from the top plate 12a of the vacuum chamber body 50, and extends to an exposed portion of the cryocooler 20 exposed from the vacuum chamber 12, that is, to a cold head drive unit 26. The cold head drive unit 26 is exposed to an environment around the vacuum chamber 12 at an upper end of the second tubular portion 54.

Further, the cryogenic device 10 includes a yoke 56 that surrounds the vacuum chamber 12. The yoke 56 is made of a magnetic material such as iron. In this example, the yoke 56 has a split structure, and includes an upper yoke 56a that surrounds an upper portion of the vacuum chamber 12 and a lower yoke 56b that surrounds a lower portion of the vacuum chamber 12. A first opening portion that receives the first tubular portion 52 of the vacuum chamber 12 is formed in the upper yoke 56a, and a gap 58 is formed between the upper yoke 56a and the first tubular portion 52 in this opening portion. Similarly, a second opening portion that receives the second tubular portion 54 of the vacuum chamber 12 is formed in the upper yoke 56a, and a gap 60 is formed between the upper yoke 56a and the second tubular portion 54 in the opening portion. The upper yoke 56a has a yoke-top surface 56a1 that surrounds the first tubular portion 52 and the second tubular portion 54.

The upper yoke 56a may be movable up and down relative to the vacuum chamber 12. For example, in a case where the maintenance of the cryogenic device 10 is performed, the upper yoke 56a may be separated from the lower yoke 56b and moved up. Accordingly, a work space through which a worker has access to the vacuum chamber 12 may be formed between the upper yoke 56a and the lower yoke 56b. In a case where the maintenance ends, the upper yoke 56a may be moved down, the work space may be closed, and the upper yoke 56a may be coupled to the lower yoke 56b again.

In this embodiment, a condensation water reservoir 44 includes two condensation water trays 44a and two condensation water guides 44b on the yoke-top surface 56a1. The condensation water trays 44a and the condensation water guides 44b are provided to correspond to the first tubular portion 52 and the second tubular portion 54, respectively.

With regard to the first tubular portion 52, the condensation water tray 44a is provided around the current introduction terminal 30 below the current introduction terminal 30. Further, the condensation water guide 44b is disposed above the gap 58 between the first tubular portion 52 and the upper yoke 56a to cover the gap 58, and is adapted to guide the condensation water, which flows down from the current introduction terminal 30, to the condensation water tray 44a. The condensation water guide 44b has an annular shape, an inner peripheral edge of the condensation water guide 44b is attached to an upper end of the first tubular portion 52 and is provided over the entire circumference of the first tubular portion 52, and an outer peripheral edge of the condensation water guide 44b is positioned above or inside the condensation water tray 44a. Therefore, water droplets adhering to the current introduction terminal 30 due to condensation flow on an upper surface of the condensation water guide 44b and are collected to the condensation water tray 44a.

Similarly, with regard to the second tubular portion 54, the condensation water tray 44a is provided around the cold head drive unit 26 below the cold head drive unit 26. In addition, the condensation water guide 44b is disposed above the gap 60 between the second tubular portion 54 and the upper yoke 56a to cover the gap 60, and is adapted to guide the condensation water, which flows down from the cold head drive unit 26, to the condensation water tray 44a. The condensation water guide 44b has an annular shape, an inner peripheral edge of the condensation water guide 44b is attached to an upper end of the second tubular portion 54 and is provided over the entire circumference of the second tubular portion 54, and an outer peripheral edge of the condensation water guide 44b is positioned above or inside the condensation water tray 44a. Therefore, water droplets adhering to the cold head drive unit 26 due to condensation flow on an upper surface of the condensation water guide 44b and are collected to the condensation water tray 44a.

Accordingly, the condensation water reservoir 44 can reduce or prevent the spread of the condensation water to the surroundings. The occurrence of rust on the yoke 56 caused by contact with the condensation water is also reduced or prevented. Further, the risk of a trouble in an electrical system, such as an electric leakage, can also be reduced.

The condensation water guide 44b may have flexibility. For example, the condensation water guide 44b may be made of an appropriate synthetic resin material, such as a silicone resin or a fluorine-based resin, in a sheet shape, and may be deformable.

Accordingly, in a case where the upper yoke 56a is moved with the condensation water tray 44a relative to the first tubular portion 52 and the second tubular portion 54, the condensation water guide 44b is deformable and thus does not hinder the movement of the upper yoke 56a and the condensation water tray 44a, which is advantageous.

The present invention has been described above based on the embodiments. It is understood by those skilled in the art that the present invention may have various design changes and various modification examples without being limited to the above-mentioned embodiments and the modification examples are also included in the scope of the present invention. Various features described in relation to a certain embodiment can also be applied to other embodiments. A new embodiment formed from the combination of embodiments has the effects of the respective combined embodiments.

A case where the cryogenic device 10 is formed of as a so-called conduction cooling type cryogenic device directly cooling the superconducting coil 14 with the cryocooler 20 has been described in the above-described embodiments by way of example. However, in a certain embodiment, the cryogenic device 10 may be an immersion cooling type cryogenic device in which the superconducting coil 14 is immersed in a cryogenic liquid refrigerant such as liquid helium. In this case, the cryocooler 20 recondenses the vaporized cryogenic liquid refrigerant to cool the superconducting coil 14.

A case where the cryocooler 20 is a two-stage GM cryocooler has been described in the above-described embodiments by way of example. However, the cryocooler 20 may be a single-stage GM cryocooler in a certain embodiment. Alternatively, the cryocooler 20 may be a pulse tube cryocooler, a Stirling cryocooler, or other types of cryocoolers, such as a single-stage or multi-stage cryocooler.

Although the present invention has been described using specific words and phrases based on the embodiment, the embodiment merely illustrates one aspect of the principle and application of the present invention. Many modification examples and changes in disposition are allowed in the embodiment without departing from the scope of the present invention defined in claims.

The present invention can be used in the field of cryogenic devices.

It should be understood that the invention is not limited to the above-described embodiment, but may be modified into various forms on the basis of the spirit of the invention. Additionally, the modifications are included in the scope of the invention.

What is claimed is:

1. A cryogenic device comprising:
a vacuum chamber;
a superconducting coil that is disposed in the vacuum chamber;
a cryocooler that is installed in the vacuum chamber to cool the superconducting coil;
a current introduction terminal that is installed in the vacuum chamber and is connected to the superconducting coil; and
a condensation water reservoir that is provided around an exposed portion, which is exposed from the vacuum chamber, of at least one of the cryocooler or the current introduction terminal, below the exposed portion.

2. The cryogenic device according to claim 1,
wherein the vacuum chamber includes
a vacuum chamber-top plate that includes an opening portion,
a first tubular portion that extends downward into the vacuum chamber from the opening portion of the vacuum chamber-top plate, and
a second tubular portion that extends downward into the first tubular portion from the exposed portion, and
the condensation water reservoir is provided between the first tubular portion and the second tubular portion.

3. The cryogenic device according to claim 1,
wherein the current introduction terminal is a hermetic terminal that is provided on a wall surface of the vacuum chamber and introduces a current from an outside of the vacuum chamber to an inside of the vacuum chamber while maintaining airtightness inside the vacuum chamber.

4. The cryogenic device according to claim 2,
wherein the first tubular portion includes an inner flange, to which the second tubular portion is to be attached, at a lower end of the first tubular portion.

5. The cryogenic device according to claim 4,
wherein the second tubular portion connects a mounting flange of the cryocooler to the first tubular portion.

6. The cryogenic device according to claim 2, further comprising:
a magnetic shield that includes a magnetic shield-upper plate provided outside the vacuum chamber and adjacent to the vacuum chamber-top plate,
wherein the condensation water reservoir is provided between the first tubular portion and the second tubular portion on one side of the vacuum chamber-top plate opposite to the magnetic shield-upper plate.

7. The cryogenic device according to claim 2,
wherein at least one of the first tubular portion or the second tubular portion is deformable.

8. The cryogenic device according to claim 1,
wherein the vacuum chamber includes a vacuum chamber body that accommodates the superconducting coil, and a tubular portion that protrudes upward from the vacuum chamber body and extends to the exposed portion,
the cryogenic device further includes a yoke that includes a yoke-top surface surrounding the tubular portion, and
the condensation water reservoir is provided on the yoke-top surface.

9. The cryogenic device according to claim 1,
wherein the cryocooler includes a first cooling stage and a second cooling stage as a low-temperature section that is to be cooled to a cryogenic temperature.

10. The cryogenic device according to claim 9, further comprising:
a radiant heat shield disposed in the vacuum chamber.

11. The cryogenic device according to claim 10,
wherein the radiant heat shield is thermally coupled to the first cooling stage and is cooled to a first cooling temperature.

12. The cryogenic device according to claim 11,
wherein the superconducting coil is thermally coupled to the second cooling stage via a heat transfer member and is cooled to a second cooling temperature lower than the first cooling temperature.

13. The cryogenic device according to claim 8,
wherein the yoke has a split structure, and includes an upper yoke that surrounds an upper portion of the vacuum chamber and a lower yoke that surrounds a lower portion of the vacuum chamber.

14. The cryogenic device according to claim 8, further comprising:
a condensation water guide that is disposed above a gap between the tubular portion and the yoke to cover the gap and is adapted to guide condensation water, which flows down from the exposed portion, to the condensation water reservoir.

15. The cryogenic device according to claim 14,
wherein the condensation water guide has flexibility.
